(19) United States
(12) Patent Application Publication
(10) Pub. No.: US 2025/0187035 A1
(43) Pub. Date: Jun. 12, 2025

(54) MASK AND METHOD OF MANUFACTURING THE SAME

(71) Applicant: Samsung Display Co., LTD., Yongin-si (KR)

(72) Inventors: YOUNGJIN SONG, Yongin-si (KR); SEUNGHUN KIM, Yongin-si (KR); SUGWOO JUNG, Yongin-si (KR); BYEONGHOON CHO, Yongin-si (KR)

(73) Assignee: Samsung Display Co., LTD., Yongin-si (KR)

(21) Appl. No.: 18/971,744

(22) Filed: Dec. 6, 2024

(30) Foreign Application Priority Data
Dec. 8, 2023 (KR) 10-2023-0177410

(51) Int. Cl. B05C 21/00

(52) U.S. Cl. CPC B05C 21/005

(57) ABSTRACT

A mask includes a support layer including a cell area and a peripheral area adjacent to the cell area and including a first opening overlapping the cell area in a plan view, and a semiconductor layer disposed on the support layer and including a plurality of second openings and a plurality of trenches recessed from a surface of the semiconductor layer adjacent to the support layer, each overlapping the first opening in a plan view.

### CROSS-REFERENCE TO RELATED APPLICATION(S)

This application claims priority to and benefits of Korean Patent Application No. 10-2023-0177410 under 35 USC § 119, filed on Dec. 8, 2023, in the Korean Intellectual Property Office (KIPO), the entire contents of which are incorporated herein by reference.

### BACKGROUND

### 1. Technical Field

Embodiments relate to a mask for deposition and a method of manufacturing the same.

### 2. Description of the Related Art

A display device is formed by stacking a plurality of layers such as a light emitting layer, a metal layer, or the like. A deposition process may be performed to form the plurality of layers of the display device. The deposition process may be performed by closely attaching a mask having the same pattern as a pattern of the light emitting layer, the metal layer, or the like to a target substrate on which deposition is to be performed. A deposition material provided from a deposition source may be deposited on the target substrate through the mask.

### SUMMARY

Embodiments provide a mask with improved reliability.

Embodiments provide a method of manufacturing the mask.

A mask according to an embodiment of the disclosure may include a support layer including a cell area and a peripheral area adjacent to the cell area and including a first opening overlapping the cell area in a plan view, and a semiconductor layer disposed on the support layer and including a plurality of second openings and a plurality of trenches recessed from a surface of the semiconductor layer adjacent to the support layer, each overlapping the first opening in a plan view.

In an embodiment, the semiconductor layer may include gallium nitride (GaN).

In an embodiment, the mask may further include a magnetic pattern disposed in the plurality of trenches.

In an embodiment, the mask may further include an insulating pattern disposed on the magnetic pattern in the plurality of trenches.

In an embodiment, the support layer may include a first support layer, and a second support layer disposed on the first support layer.

In an embodiment, the first support layer may include silicon, and the second support layer may include a metal.

In an embodiment, the support layer and the semiconductor layer may be adhered by the second support layer.

In an embodiment, the plurality of second openings and the plurality of trenches may be alternately arranged in a direction in the cell area.

A method of manufacturing a mask according to an embodiment of the disclosure may include forming a preliminary semiconductor layer on a substrate including a cell area and a peripheral area adjacent to the cell area, the preliminary semiconductor layer including a plurality of trenches recessed from a surface of the preliminary semiconductor layer spaced apart from the substrate and overlapping the cell area in a plan view, forming a support layer including a first opening overlapping the plurality of trenches in a plan view on the preliminary semiconductor layer, and forming a semiconductor layer including a plurality of second openings overlapping the first opening in a plan view by etching the preliminary semiconductor layer.

In an embodiment, the semiconductor layer may include gallium nitride (GaN).

In an embodiment, the method may further include forming a magnetic pattern in the plurality of trenches after the forming of the preliminary semiconductor layer and before the forming of the support layer.

In an embodiment, the method may further include forming an insulating pattern on the magnetic pattern in the plurality of trenches after the forming of the magnetic pattern and before the forming of the support layer.

In an embodiment, the forming of the support layer may include forming a preliminary support layer on the preliminary semiconductor layer, and forming a first support layer disposed on the preliminary semiconductor layer and a second support layer disposed between the preliminary semiconductor layer and the first support layer by etching the preliminary support layer.

In an embodiment, the first support layer may include silicon, and the second support layer may include a metal.

In an embodiment, the method may further include removing the substrate after the forming of the support layer and before the forming of the semiconductor layer.

In an embodiment, the substrate may include sapphire.

In an embodiment, in the removing of the substrate, the substrate may be removed by irradiating a laser to the substrate.

In an embodiment, the substrate may include silicon.

In an embodiment, in the removing of the substrate, the substrate may be removed by grinding the substrate.

In an embodiment, in the forming of the semiconductor layer, the plurality of second openings may be formed not to overlap the plurality of trenches in a plan view.

In a mask according to embodiments of the disclosure, the mask may include a semiconductor layer including gallium nitride and a magnetic pattern including a magnetic material. Since rigidity of the semiconductor layer may be relatively high, even when manufacturing a high-resolution display device, deformation such as sagging of the mask, damage to the mask, or the like may be prevented. Since the magnetic pattern may be magnetic, deformation such as sagging of the mask may be further prevented. Accordingly, reliability of the mask may be improved, and efficiency of a process using the mask may be improved. Since the semiconductor layer may be chemically stable, the mask may be readily manufactured. Accordingly, efficiency of a manufacturing process of the mask may be improved.

### BRIEF DESCRIPTION OF THE DRAWINGS

FIG. 1 is a perspective view illustrating a mask according to an embodiment of the disclosure.

FIG. 2 is an enlarged plan view of a portion of a cell area of the mask of FIG. 1.

FIG. 3 is a schematic cross-sectional view taken along line I-I′ of FIG. 1.

FIGS. 4, 5, 6, 7, 8, 9, 10, 11, 12, 13, 14, and 15 are views illustrating a method of manufacturing a mask according to an embodiment of the disclosure.

FIG. 16 is a schematic cross-sectional view illustrating an apparatus for manufacturing a display device according to an embodiment of the disclosure.

### DETAILED DESCRIPTION OF THE EMBODIMENTS

Hereinafter, embodiments of the disclosure will be described in more detail with reference to the accompanying drawings. The same reference numerals are used for the same components in the drawings, and redundant descriptions of the same components will be omitted.

Unless otherwise specified, the illustrated embodiments are to be understood as providing exemplary features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

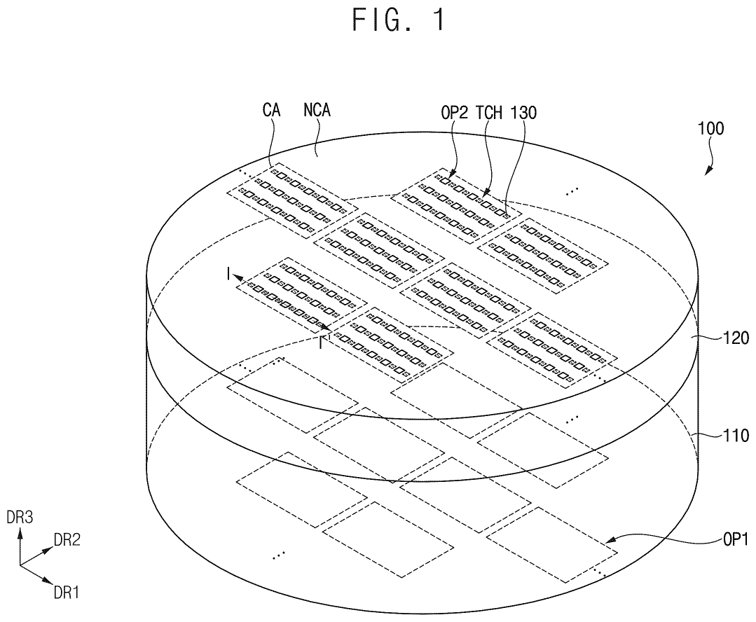

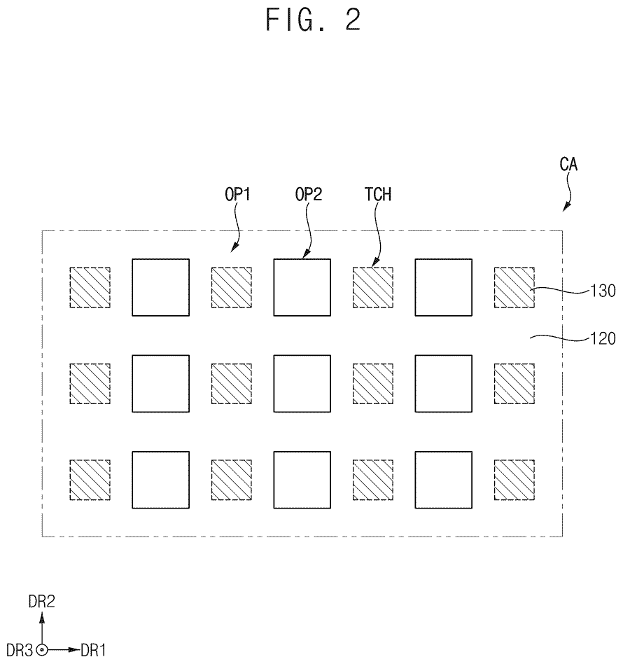

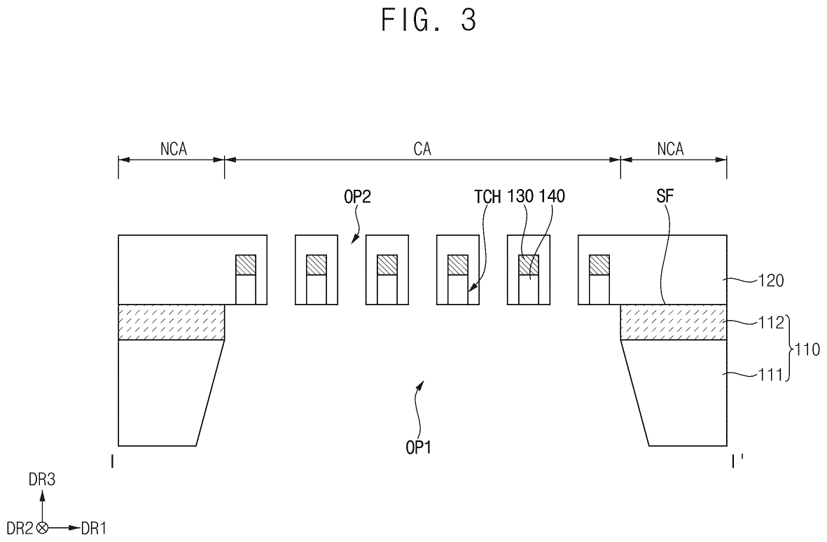

FIG. 1 is a perspective view illustrating a mask according to an embodiment of the disclosure. FIG. 2 is an enlarged plan view of a portion of a cell area of the mask of FIG. 1. FIG. 3 is a schematic cross-sectional view taken along line I-I′ of FIG. 1.

Referring to FIGS. 1, 2, and 3, a mask 100 may extend parallel to a plane defined by a first direction DR1 and a second direction DR2 intersecting the first direction DR1. For example, the first direction DR1 and the second direction DR2 may be perpendicular.

The mask 100 may be used in a manufacturing process of a display device. For example, the mask 100 may be used in a process of depositing a light emitting layer on a target substrate during the manufacturing process of the display device. However, the disclosure is not limited thereto, and the mask 100 may be used in various deposition processes during the manufacturing process of the display device.

In an embodiment, the display device may be a micro light emitting diode display device including a micro light emitting diode as a light emitting element. However, the disclosure is not limited thereto, and in another embodiment, the display device may be an organic light emitting diode display device including an organic light emitting diode as a light emitting element.

The mask 100 may include a cell area CA and a peripheral area NCA adjacent to the cell area CA.

The cell area CA may be an area corresponding to an area in which a deposition material is deposited on the target substrate. The mask 100 may include multiple cell areas CA. The cell areas CA may be repeatedly arranged in the first direction DR1 or in the second direction DR2, and may be spaced apart from each other. For example, the cell areas CA may be arranged in a matrix form in the first direction DR1 and the second direction DR2. In another embodiment, the cell areas CA may be arranged in either the first direction DR1 or the second direction DR2.

The peripheral area NCA may be an area corresponding to an area in which the deposition material is not deposited on the target substrate. The peripheral area NCA may surround the cell area CA in a plan view. The peripheral area NCA may be defined such that the cell areas CA are spaced apart from each other with the peripheral area NCA interposed between the cell areas CA.

Although FIG. 1 illustrates that the cell area CA has a quadrangular shape in a plan view, the disclosure is not limited thereto. For example, a shape of the cell area CA may be variously modified according to a shape of the display device.

The mask 100 may include a support layer 110 and a semiconductor layer 120. As the mask 100 may include the cell area CA and the peripheral area NCA, the support layer 110 and the semiconductor layer 120 may also include the cell area CA and the peripheral area NCA.

The support layer 110 may include a first support layer 111 and a second support layer 112. The second support layer 112 may be disposed on the first support layer 111. In an embodiment, the first support layer 111 may include silicon (Si), and the second support layer 112 may include a metal. For example, the first support layer 111 may be a silicon wafer, and the second support layer 112 may include nickel (Ni), iron (Fe), aluminum (Al), the like, or a combination thereof.

The support layer 110 may include a first opening OP1. The first opening OP1 may penetrate the support layer 110 in a third direction DR3 intersecting each of the first direction DR1 and the second direction DR2.

The support layer 110 may include multiple first openings OP1. The first opening OP1 may overlap the cell area CA in a plan view. For example, the first opening OP1 may entirely overlap the cell area CA in a plan view. For example, in a plan view, the support layer 110 may overlap the peripheral area NCA, and may not overlap the cell area CA. The first openings OP1 may be repeatedly arranged in the first direction DR1 or in the second direction DR2 to overlap the cell areas CA in a plan view, and may be spaced apart from each other.

Although FIG. 1 schematically illustrates that the first opening OP1 has a quadrangular shape in a plan view, the disclosure is not limited thereto. For example, a shape of the first opening OP1 may be variously modified according to the shape of the display device.

The semiconductor layer 120 may be disposed on the support layer 110. The semiconductor layer 120 may include a semiconductor material. In an embodiment, the semiconductor layer 120 may include gallium nitride (GaN). Accordingly, the semiconductor layer 120 may have relatively high rigidity, and may be chemically stable. The semiconductor layer 120 may be supported by the support layer 110, and the semiconductor layer 120 may be adhered to the support layer 110 by the second support layer 112.

The semiconductor layer 120 may include multiple second openings OP2 overlapping the first opening OP1 defined by the support layer 110 in a plan view. The second openings OP2 may overlap the cell area CA and the first opening OP1 in a plan view. The second openings OP2 may not overlap the peripheral area NCA and the support layer 110 in a plan view.

The second opening OP2 may penetrate the semiconductor layer 120 in the third direction DR3. The second openings OP2 may be connected to the first opening OP1 in the cell area CA. For example, in the cell area CA, the first opening OP1 and the second openings OP2 may penetrate the mask 100 in the third direction DR3.

The second openings OP2 may be repeatedly arranged in the first direction DR1 or in the second direction DR2 in the cell area CA, and may be spaced apart from each other. For example, the second openings OP2 may be arranged in a matrix form in the first direction DR1 and the second direction DR2 in the cell area CA. In another embodiment, the second openings OP2 may be arranged in either the first direction DR1 or the second direction DR2 in the cell area CA.

Although FIG. 1 illustrates that a number of the second openings OP2 overlapping the first opening OP1 in the cell area CA is 15, and FIGS. 1 and 2 illustrate that the second opening OP2 has a quadrangular shape in a plan view, the disclosure is not limited thereto. For example, in the cell area CA, the number of the second openings OP2 overlapping the first opening OP1 and a shape of the second opening OP2 may be variously modified according to a pattern of a layer deposited through the mask 100.

The semiconductor layer 120 may further include multiple trenches TCH overlapping the first opening OP1 defined by the support layer 110 in a plan view. The trenches TCH may overlap the cell area CA and the first opening OP1 in a plan view. The trenches TCH may not overlap the peripheral area NCA and the support layer 110 in a plan view.

The trenches TCH may be recessed in the third direction DR3 from a surface SF of the semiconductor layer 120 adjacent to the support layer 110. The trenches TCH may be connected to the first opening OP1 in the cell area CA.

The trenches TCH may be repeatedly arranged in the first direction DR1 or in the second direction DR2 in the cell area CA, and may be spaced apart from each other. For example, the trenches TCH may be arranged in a matrix form in the first direction DR1 and the second direction DR2 in the cell area CA. In another embodiment, the trenches TCH may be arranged in either the first direction DR1 or the second direction DR2 in the cell area CA.

The trenches TCH and the second openings OP2 may not overlap each other in a plan view. For example, the trenches TCH and the second openings OP2 may be alternately arranged in the first direction DR1 in the cell area CA. However, the disclosure is not limited thereto, and in another embodiment, the trenches TCH and the second openings OP2 may be alternately arranged in the second direction DR2, or may be alternately arranged in the first direction DR1 and the second direction DR2.

Although FIG. 1 illustrates that a number of the trenches TCH overlapping the first opening OP1 in the cell area CA is 18, and FIGS. 1 and 2 illustrate that the trench TCH has a quadrangular shape in a plan view, the disclosure is not limited thereto. For example, in the cell area CA, the number of the trenches TCH overlapping the first opening OP1 and a shape of the trench TCH may be variously modified.

Although FIG. 2 illustrates that a planar area of the trench TCH is smaller than a planar area of the second opening OP2, the disclosure is not limited thereto. For example, the planar area of each of the trench TCH and the second opening OP2 may be variously modified.

The mask 100 may further include a magnetic pattern 130 and an insulating pattern 140.

The magnetic pattern 130 may be disposed in the trenches TCH defined by the semiconductor layer 120. In an embodiment, the magnetic pattern 130 may include a magnetic metal. For example, the magnetic pattern 130 may include nickel (Ni), iron (Fe), cobalt (Co), the like, or a combination thereof, but the disclosure is not limited thereto.

The insulating pattern 140 may be disposed on the magnetic pattern 130 in the trenches TCH defined by the semiconductor layer 120. The insulating pattern 140 may cover the magnetic pattern 130. For example, the insulating pattern 140 may include an inorganic material such as silicon oxide (SiOₓ), silicon nitride (SiNₓ), silicon oxynitride (SiOₓN_{y}), the like, or a combination thereof.

The mask 100 according to an embodiment of the disclosure may include the semiconductor layer 120 including gallium nitride and the magnetic pattern 130 including a magnetic material. Since the rigidity of the semiconductor layer 120 may be relatively high, even when manufacturing a high-resolution display device, deformation such as sagging of the mask 100, damage to the mask 100, or the like may be prevented. Since the magnetic pattern 130 may be magnetic, deformation such as sagging of the mask 100 may be further prevented. Accordingly, the mask 100 may be readily reused, and efficiency of a process using the mask 100 may be improved. Since the semiconductor layer 120 may be chemically stable, the mask 100 may be readily manufactured. Accordingly, efficiency of a manufacturing process of the mask 100 may be improved.

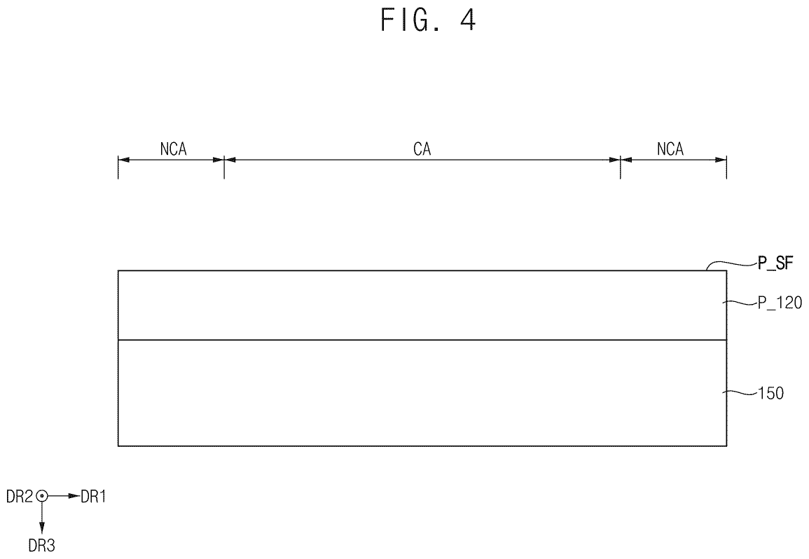

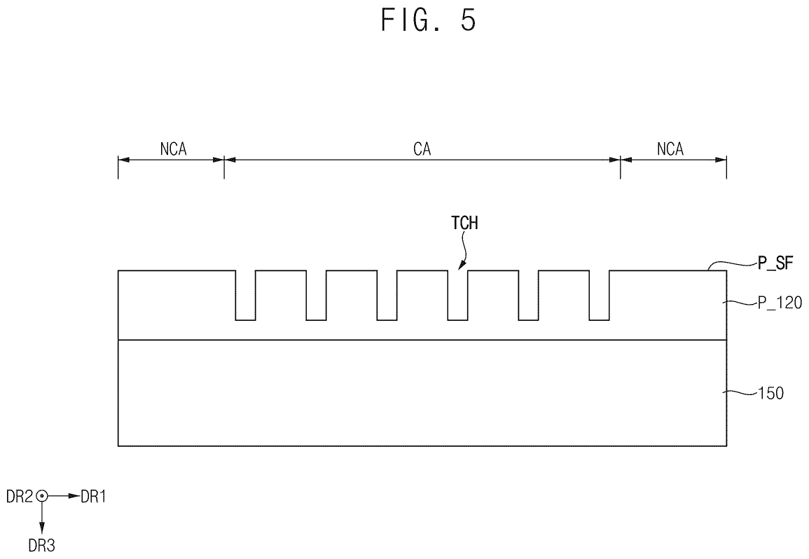

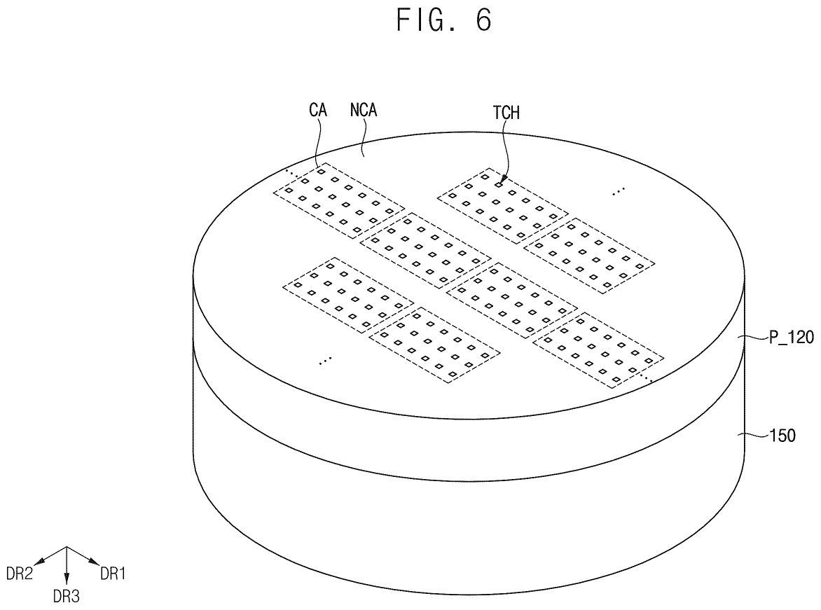

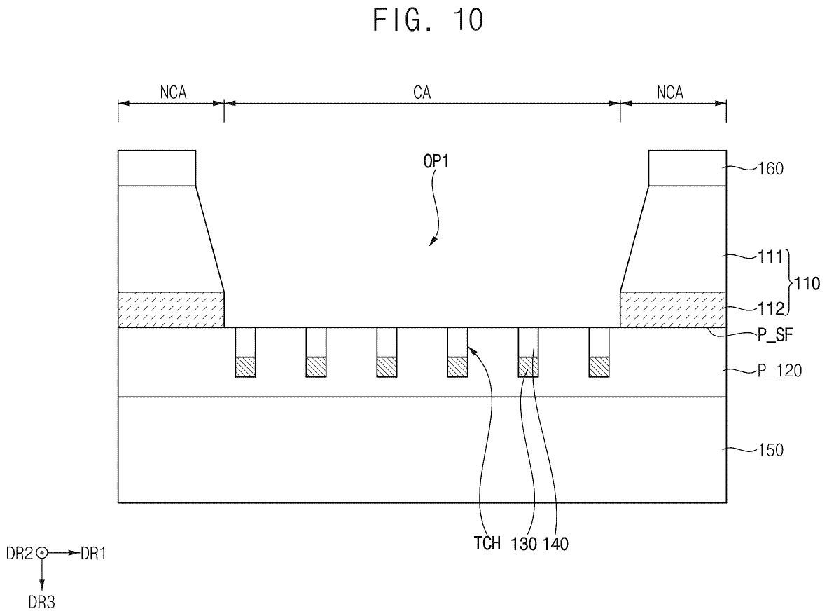

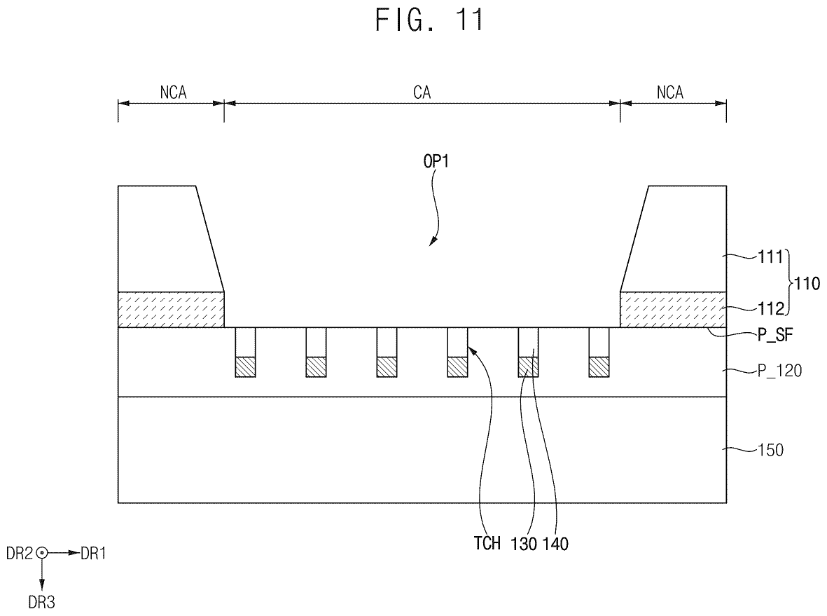

FIGS. 4, 5, 6, 7, 8, 9, 10, 11, 12, 13, 14, and 15 are views illustrating a method of manufacturing a mask according to an embodiment of the disclosure.

For example, a method of manufacturing a mask described with reference to FIGS. 4, 5, 6, 7, 8, 9, 10, 11, 12, 13, 14, and 15 may be a method of manufacturing the mask 100 described with reference to FIGS. 1, 2, and 3. Hereinafter, redundant descriptions will be omitted or simplified.

Referring to FIGS. 4, 5, and 6, a preliminary semiconductor layer P_120 may be formed on a substrate 150. The substrate 150 and the preliminary semiconductor layer P_120 may include a cell area CA and a peripheral area NCA.

The mask 100 may include multiple cell areas CA. The cell areas CA may be repeatedly arranged in a first direction DR1 or in a second direction DR2, and may be spaced apart from each other. The peripheral area NCA may surround the cell area CA in a plan view.

In an embodiment, the substrate 150 may include sapphire, and the preliminary semiconductor layer P_120 may include gallium nitride. In another embodiment, the substrate 150 may include silicon, and the preliminary semiconductor layer P_120 may include gallium nitride.

Multiple trenches TCH overlapping the cell area CA in a plan view may be formed on the preliminary semiconductor layer P_120. The trenches TCH may be formed by being recessed in a third direction DR3 from a surface P_SF of the preliminary semiconductor layer P_120 spaced apart from the substrate 150. The trenches TCH may be repeatedly arranged in the first direction DR1 or in the second direction DR2 in the cell area CA, and may be spaced apart from each other. For example, the trenches TCH may be formed using a photoresist pattern formed on the surface P_SF of the preliminary semiconductor layer P_120.

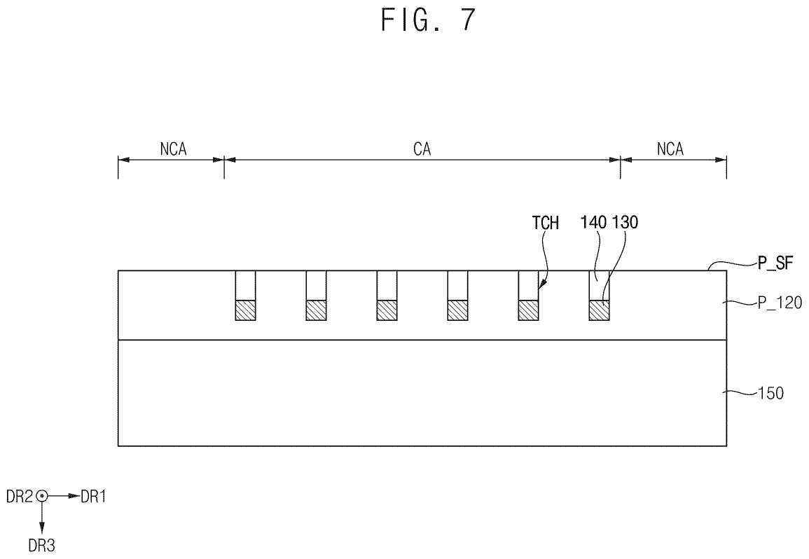

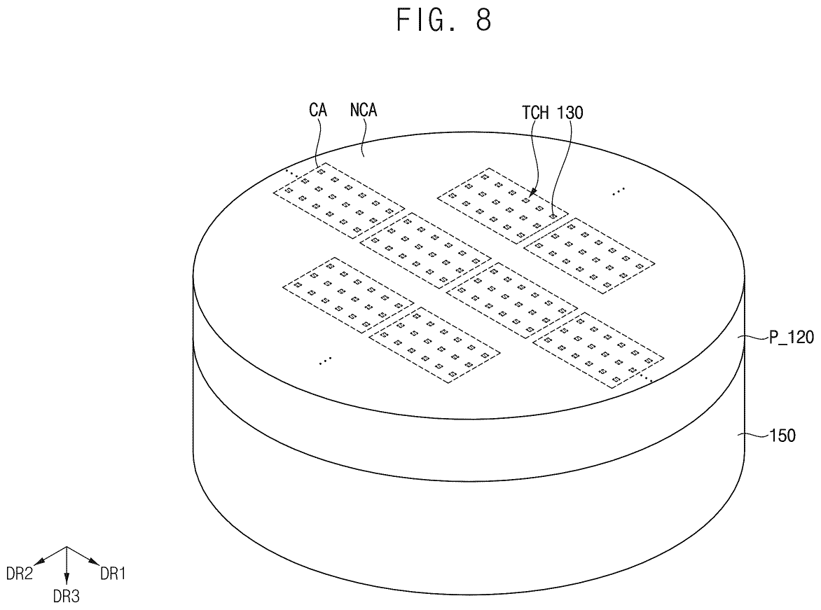

Referring to FIGS. 7 and 8, a magnetic pattern 130 may be formed in the trenches TCH.

For example, a magnetic layer may be formed in the trenches TCH and on the photoresist pattern. A portion of the magnetic layer may be formed in the trenches TCH, and another portion of the magnetic layer may be formed on the photoresist pattern. Thereafter, the magnetic layer formed on the photoresist pattern and the photoresist pattern may be removed to form the magnetic pattern 130. In an embodiment, the magnetic pattern 130 may include a magnetic metal.

An insulating pattern 140 may be formed on the magnetic pattern 130 in the trenches TCH. The insulating pattern 140 may cover the magnetic pattern 130 in the trenches TCH. The insulating pattern 140 and the magnetic pattern 130 may fill the trenches TCH.

For example, an insulating layer may be formed on the magnetic pattern 130. Thereafter, the insulating layer may be polished through a chemical mechanical polishing (CMP) process or the like to form the insulating pattern 140. For example, the insulating layer may be polished such that an upper surface of the insulating pattern 140 and the surface P_SF of the preliminary semiconductor layer P_120 have a same level. For example, the insulating pattern 140 may include an inorganic material such as silicon oxide, silicon nitride, silicon oxynitride, the like, or a combination thereof.

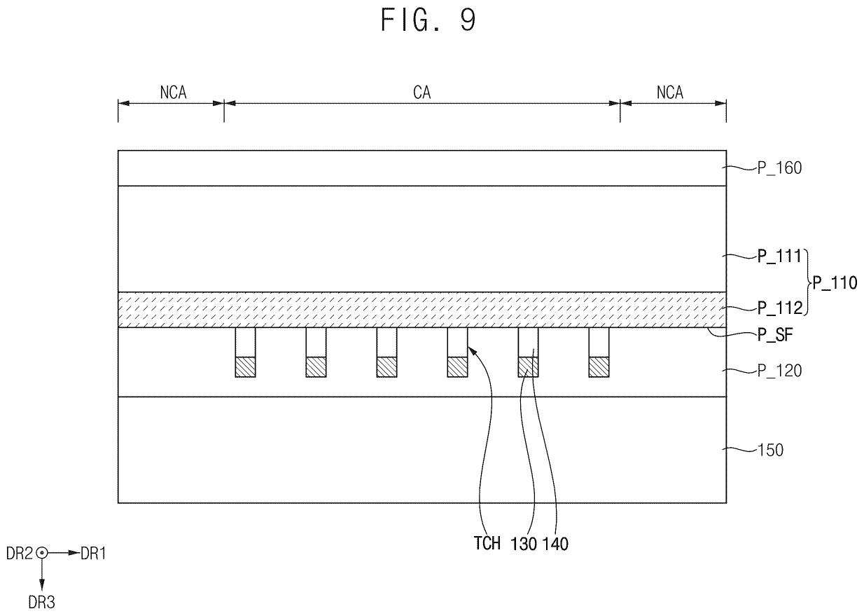

Referring to FIG. 9, a preliminary support layer P_110 and a preliminary hard mask P_160 may be sequentially formed on the surface P_SF of the preliminary semiconductor layer P 120 and the insulating pattern 140.

The preliminary support layer P_110 may include a preliminary first support layer P_111 and a preliminary second support layer P_112. The preliminary first support layer P_111 may be disposed on the preliminary semiconductor layer P_120, and the preliminary second support layer P_112 may be disposed between the preliminary semiconductor layer P_120 and the preliminary first support layer P_111. In an embodiment, the preliminary first support layer P_111 may include silicon, and the preliminary second support layer P_112 may include a metal. The preliminary support layer P_110 may be adhered to the preliminary semiconductor layer P_120 by the preliminary second support layer P_112.

Referring to FIGS. 9, 10, 11, and 12, the preliminary hard mask P_160 may be etched to form a hard mask 160. For example, the preliminary hard mask P_160 may be etched using a photoresist pattern formed on the preliminary hard mask P_160 to form the hard mask 160, and the photoresist pattern may be removed. In a plan view, the hard mask 160 may overlap the peripheral area NCA, and may not overlap the cell area CA.

Thereafter, the preliminary support layer P_110 may be etched to form a support layer 110. For example, the preliminary support layer P_110 may be etched using the hard mask 160. As the preliminary support layer P_110 is etched, a first opening OP1 may be formed. The first opening OP1 may overlap the cell area CA in a plan view. The first opening OP1 may be formed in plural. The first openings OP1 may be repeatedly arranged in the first direction DR1 or in the second direction DR2 to overlap the cell areas CA in a plan view, and may be spaced apart from each other.

The first opening OP1 may penetrate the support layer 110 in the third direction DR3. The support layer 110 may include the first opening OP1 penetrating the support layer 110 in the third direction DR3 in the cell area CA. For example, in a plan view, the support layer 110 may not overlap the cell area CA, and may overlap the peripheral area NCA. The surface P_SF of the preliminary semiconductor layer P_120 and the trenches TCH overlapping the cell area CA may be exposed by the first opening OP1.

The support layer 110 may include a first support layer 111 and a second support layer 112. The preliminary first support layer P_111 may be etched to form the first support layer 111, and the preliminary second support layer P_112 may be etched to from the second support layer 112. For example, the first support layer 111 may be formed by wet etching the preliminary first support layer P_111, and the second support layer 112 may be formed by dry etching the preliminary second support layer P_112.

The first support layer 111 may be disposed on the preliminary semiconductor layer P_120, and the second support layer 112 may be disposed between the preliminary semiconductor layer P_120 and the first support layer 111. The first support layer 111 may include silicon, and the second support layer 112 may include a metal. The support layer 110 and the preliminary semiconductor layer P_120 may be adhered by the second support layer 112. After forming the support layer 110, the hard mask 160 may be removed.

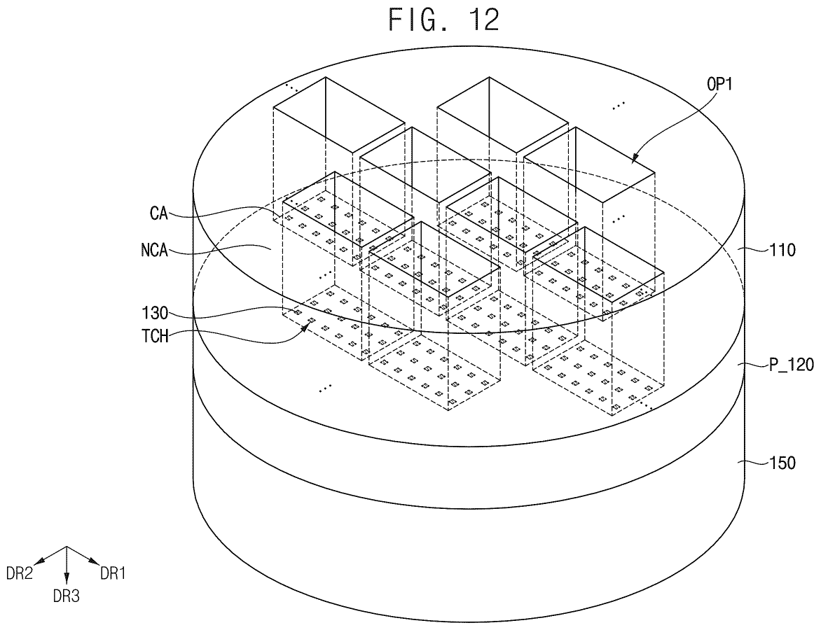

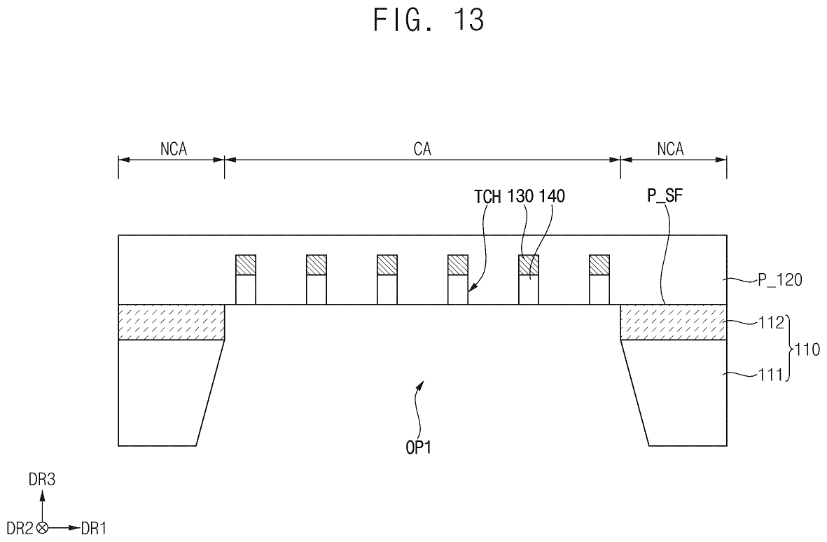

Referring to FIGS. 12 and 13, the substrate 150 may be removed. By removing the substrate 150, the preliminary semiconductor layer P_120 may be supported by the support layer 110.

In an embodiment, in case that the substrate 150 includes sapphire, the substrate 150 may be removed by irradiating a laser to the substrate 150. For example, a laser lift-off process to remove the substrate 150 may be performed.

In another embodiment, in case that the substrate 150 includes silicon, the substrate 150 may be removed by grinding the substrate 150, and after grinding the substrate 150, residues of the substrate 150 may be removed through dry etching.

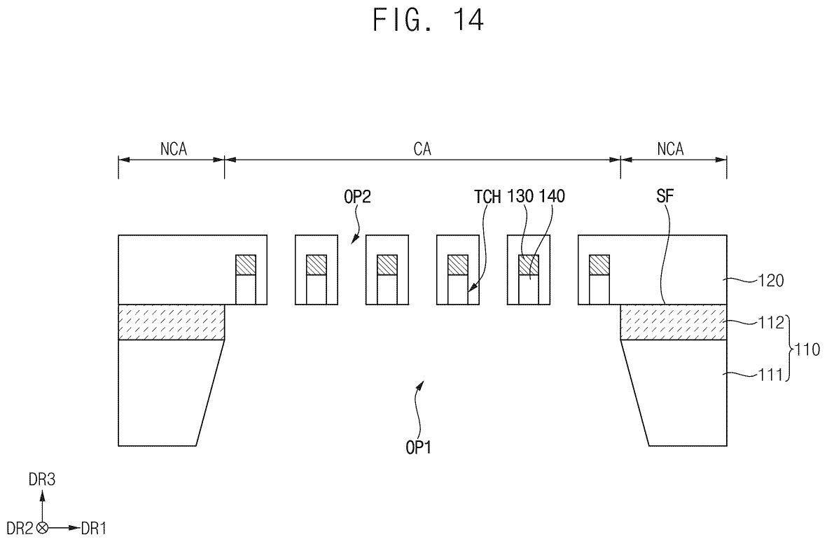

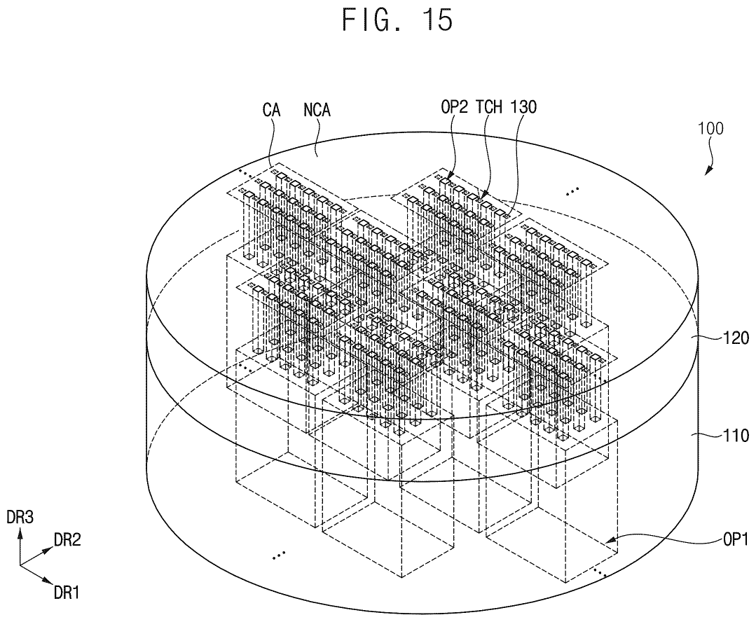

Referring to FIGS. 14 and 15, the preliminary semiconductor layer P_120 may be etched to form a semiconductor layer 120. For example, the preliminary semiconductor layer P_120 may be etched using a photoresist pattern formed on a surface of the preliminary semiconductor layer P_120 spaced apart from the support layer 110.

As the preliminary semiconductor layer P_120 is etched, multiple second openings OP2 may be formed. The second openings OP2 may overlap the cell area CA and the first opening OP1 in a plan view. For example, the second openings OP2 may be connected to the first opening OP1 in the cell area CA. The second openings OP2 may be repeatedly arranged in the first direction DR1 or in the second direction DR2 in the cell area CA, and may be spaced apart from each other.

The second openings OP2 may not overlap the trenches TCH in a plan view. For example, the second openings OP2 and the trenches TCH may be alternately formed in the first direction DR1 in the cell area CA. However, the disclosure is not limited thereto, and in another embodiment, the second openings OP2 and the trenches TCH may be alternately formed in the second direction DR2 in the cell area CA, or may be alternately formed in the first direction DR1 and the second direction DR2 in the cell area CA.

The second openings OP2 may penetrate the semiconductor layer 120 in the third direction DR3. The semiconductor layer 120 may include the second openings OP2 penetrating the semiconductor layer 120 in the third direction DR3 in the cell area CA. The semiconductor layer 120 may include the trenches TCH recessed in the third direction DR3 from a surface SF of the semiconductor layer 120 adjacent to the support layer 110 in the cell area CA.

Accordingly, the mask 100 including the first openings OP1 and the second openings OP2 penetrating the mask 100 in the third direction DR3 in the cell areas CA and including the magnetic pattern 130 that is magnetic may be manufactured.

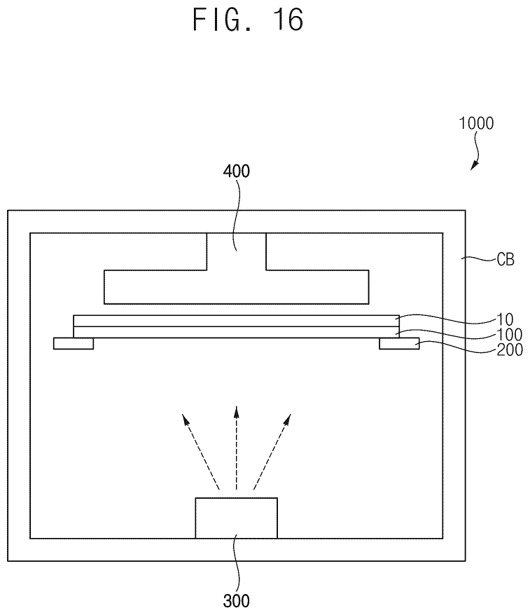

FIG. 16 is a schematic cross-sectional view illustrating an apparatus for manufacturing a display device according to an embodiment of the disclosure.

For example, an apparatus 1000 for manufacturing a display device described with reference to FIG. 16 may be an apparatus using the mask 100 described with reference to FIGS. 1, 2, and 3. Hereinafter, redundant descriptions will be omitted or simplified.

Referring to FIGS. 1 and 16, the apparatus 1000 for manufacturing the display device may include a chamber CB, a mask 100, a support portion 200, a deposition source 300, and a magnetic plate 400.

The chamber CB may include an empty space. The chamber CB may include a space in which a deposition process is performed. In an embodiment, the deposition process may be performed by evaporating a deposition material and depositing the deposition material on a target substrate 10. During the deposition process, inside of the chamber CB may be maintained in a vacuum state.

Each of the mask 100, the support portion 200, the deposition source 300, and the magnetic plate 400 may be disposed inside the chamber CB.

The support portion 200 may support the mask 100. The support portion 200 may finely adjust a position of the mask 100. For example, the support portion 200 may be fixed inside the chamber CB. However, the disclosure is not limited thereto, and in another embodiment, the support portion 200 may be in a form of a shuttle movable inside or outside the chamber CB.

The deposition source 300 may be disposed to face the mask 100. For example, the deposition source 300 may be disposed below the mask 100. The deposition source 300 may provide the deposition material to the target substrate 10 disposed on the mask 100. For example, the deposition source 300 may evaporate or sublimate the deposition material to provide the deposition material toward the target substrate 10. The deposition material may be deposited on the target substrate 10 through the mask 100. For example, the deposition source 300 may provide an organic material that forms a light emitting layer, but the disclosure is not limited thereto.

The magnetic plate 400 may be disposed to face the mask 100 in a direction opposite to the deposition source 300. For example, the magnetic plate 400 may be disposed on the mask 100. For example, the magnetic plate 400 may face the deposition source 300 with the mask 100 interposed between the magnetic plate 400 and the deposition source 300.

The magnetic plate 400 may apply a magnetic force to the mask 100 to force the mask 100 in a direction toward the target substrate 10. The magnetic plate 400 may attract the mask 100 including the magnetic pattern 130 by an attractive force. Accordingly, the magnetic plate 400 may prevent the mask 100 from being sagging. The magnetic plate 400 may increase adhesion between the mask 100 and the target substrate 10, and may uniformly maintain a gap between the mask 100 and the target substrate 10. For example, the magnetic plate 400 may include a magnetic chuck.

In case that the target substrate 10 is input into the chamber CB, the target substrate 10 may be disposed on the mask 100. The mask 100 may be adjacent to the target substrate 10 by the magnetic plate 400, and the deposition source 300 may provide the deposition material toward the target substrate 10. The deposition material may pass through the mask 100 and be deposited on the target substrate 10. For example, the deposition material may pass through first openings OP1 and second openings OP2 penetrating the mask 100 and be deposited on the target substrate 10. Accordingly, the deposition material may be deposited on the target substrate 10 in a pattern corresponding to a pattern of the mask 100.

The disclosure may be applied to a manufacturing process of various display devices. For example, the disclosure may be applicable to a manufacturing process of various display devices such as display devices for vehicles, ships and aircraft, portable communication devices, display devices for exhibition or information transmission, medical display devices, and the like.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A mask comprising:
a support layer comprising a cell area and a peripheral area adjacent to the cell area and including a first opening overlapping the cell area in a plan view; and
a semiconductor layer disposed on the support layer and including a plurality of second openings and a plurality of trenches recessed from a surface of the semiconductor layer adjacent to the support layer, each overlapping the first opening in a plan view.

2. The mask of claim 1, wherein the semiconductor layer includes gallium nitride (GaN).

3. The mask of claim 1, further comprising:
a magnetic pattern disposed in the plurality of trenches.

4. The mask of claim 3, further comprising:
an insulating pattern disposed on the magnetic pattern in the plurality of trenches.

5. The mask of claim 1, wherein the support layer includes:
a first support layer; and
a second support layer disposed on the first support layer.

6. The mask of claim 5, wherein
the first support layer includes silicon, and
the second support layer includes a metal.

7. The mask of claim 6, wherein the support layer and the semiconductor layer are adhered by the second support layer.

8. The mask of claim 1, wherein the plurality of second openings and the plurality of trenches are alternately arranged in a direction in the cell area.

9. A method of manufacturing a mask, the method comprising:
forming a preliminary semiconductor layer on a substrate comprising a cell area and a peripheral area adjacent to the cell area, the preliminary semiconductor layer including a plurality of trenches recessed from a surface of the preliminary semiconductor layer spaced apart from the substrate and overlapping the cell area in a plan view;
forming a support layer including a first opening overlapping the plurality of trenches in a plan view on the preliminary semiconductor layer; and
forming a semiconductor layer including a plurality of second openings overlapping the first opening in a plan view by etching the preliminary semiconductor layer.

10. The method of claim 9, wherein the semiconductor layer includes gallium nitride (GaN).

11. The method of claim 9, further comprising:
forming a magnetic pattern in the plurality of trenches after the forming of the preliminary semiconductor layer and before the forming of the support layer.

12. The method of claim 11, further comprising:
forming an insulating pattern on the magnetic pattern in the plurality of trenches after the forming of the magnetic pattern and before the forming of the support layer.

13. The method of claim 9, wherein the forming of the support layer includes:
forming a preliminary support layer on the preliminary semiconductor layer; and
forming a first support layer disposed on the preliminary semiconductor layer and a second support layer disposed between the preliminary semiconductor layer and the first support layer by etching the preliminary support layer.

14. The method of claim 13, wherein
the first support layer includes silicon, and
the second support layer includes a metal.

15. The method of claim 9, further comprising:
removing the substrate after the forming of the support layer and before the forming of the semiconductor layer.

16. The method of claim 15, wherein the substrate includes sapphire.

17. The method of claim 16, wherein in the removing of the substrate,
the substrate is removed by irradiating a laser to the substrate.

18. The method of claim 15, wherein the substrate includes silicon.

19. The method of claim 18, wherein in the removing of the substrate,
the substrate is removed by grinding the substrate.

20. The method of claim 9, wherein in the forming of the semiconductor layer,
the plurality of second openings are formed not to overlap the plurality of trenches in a plan view.
